(19) United States
(12) Patent Application Publication
(10) Pub. No.: US 2025/0201743 A1
(43) Pub. Date: Jun. 19, 2025

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventor: Bogeng Guo, Quanzhou City (CN)

(73) Assignee: Fujian Jinhua Integrated Circuit Co., Ltd., Quanzhou City (CN)

(21) Appl. No.: 18/786,617

(22) Filed: Jul. 29, 2024

(30) Foreign Application Priority Data
Dec. 19, 2023 (CN) 202311769048.4
Dec. 19, 2023 (CN) 202323496689.5

(51) Int. Cl. H01L 23/00; H01L 27/02

(52) U.S. Cl. CPC H01L 24/06; H01L 24/03; H01L 24/05; H10D 89/10; H01L 2224/03903; H01L 2224/05012; H01L 2224/06131; H01L 2924/1436

(57) ABSTRACT

The present disclosure provides a semiconductor device and a method of fabricating the same, including a substrate, an extension pad array and a margin structure. The extension pad array is disposed on the substrate and includes a plurality of extension pads separately arranged along a first direction and a second direction. The margin structure is disposed outside the extension pad array and includes a plurality of first protrusions, and a plurality of second protrusions respectively contacting one corresponding first protrusion, wherein a side face of one of the first protrusions and a side face of one of the second protrusions adjacent to each other define an acute angle therebetween, and a portion of the extension pads is disposed between the two adjacent side faces.

### BACKGROUND OF THE INVENTION

### 1. Field of the Invention

The present disclosure generally relates to a semiconductor device and a method of fabricating the same, and more particularly, to a semiconductor device including extension pads, and a method of fabricating the same.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

An object of the present disclosure is to provide a semiconductor device, where a margin structure is arranged to include several protrusions for improving the device reliability and the structural stability of the margin structure to the semiconductor device. Thus, the semiconductor device may therefore gain better components, to achieve an optimized operation and performance.

Another object of the present disclosure is to provide a method of fabricating a semiconductor device, in which a margin structure including several protrusions is defined through additionally forming a blocking pattern, so as to fabricate the semiconductor device with improved device reliability and the structural stability, to achieve an optimized operation and performance thereby.

In order to achieve the above object, an embodiment of the present disclosure provides a semiconductor device, including a substrate, an extension pad array and a margin structure. The extension pad array includes a plurality of extension pads disposed on the substrate, with the extension pads being separately arranged in a first direction and in a second direction. The margin structure is disposed outside the extension pad array and includes a plurality of first protrusions and a plurality of second protrusions respectively contacting each of the first protrusions, wherein a side face of one of the first protrusions and a side face of one of the second protrusions adjacent to each other define an acute angle therebetween, and a portion of the extension pads is disposed between the side face of the first protrusion and the side face of the second protrusion.

In order to achieve the above object, an embodiment of the present disclosure provides a semiconductor device, including a substrate, an extension pad array, a margin structure and a plurality of capacitors. The extension pad array is disposed on the substrate and includes a plurality of extension pads separately arranged in a first direction and in a second direction. The margin structure is disposed outside the extension pad array and includes a plurality of protrusions, wherein each of the protrusions includes a V-shaped recess. The capacitors are respectively disposed on the V-shaped recess of each of the protrusions.

In order to achieve the above object, an embodiment of the present disclosure provides a method of fabricating a semiconductor device, including the following steps. A substrate is provided, and an extension pad array is formed on the substrate, with the extension pad array including a plurality of extension pads separately arranged along a first direction and a second direction. A margin structure is formed outside the extension pad array, and the margin structure includes a plurality of first protrusions and a plurality of second protrusions respectively contacting each of the first protrusions. A side face of one of the first protrusions and a side face of one of the second protrusions adjacent to each other define an acute angle therebetween, and a portion of the extension pads is disposed between the side face of the first protrusion and the side face of the second protrusion.

Overall speaking, through arranging the margin structure having the protrusions, the semiconductor device of the present disclosure is allowable to enhance the device reliability and the structural stability of the semiconductor device, such that, the semiconductor device of the present disclosure may therefore gain an optimized operation and performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic diagram illustrating a top view of a semiconductor device according to a first embodiment in the present disclosure.

FIG. 2 to FIG. 6 are schematic diagrams illustrating a method of fabricating the semiconductor device according to the first embodiment of the present disclosure, wherein;

FIG. 2 is a schematic top view of a semiconductor device after forming a first mask layer;

FIG. 3 is a schematic top view of a semiconductor device after performing an etching process;

FIG. 4 is a schematic top view of a semiconductor device after forming a second mask layer;

FIG. 5 is a schematic top view of a semiconductor device after forming mask patterns; and

FIG. 6 is a schematic top view of a semiconductor device after forming a blocking pattern.

FIG. 7 to FIG. 8 are schematic diagrams illustrating a method of fabricating the semiconductor device according to a second embodiment of the present disclosure, wherein:

FIG. 7 is a schematic top view of a semiconductor device after forming a blocking pattern; and

FIG. 8 is a schematic top view of a semiconductor device according to the second embodiment of the present disclosure.

FIG. 9 to FIG. 10 are schematic diagrams illustrating a method of fabricating the semiconductor device according to a third embodiment of the present disclosure, wherein:

FIG. 9 is a schematic top view of a semiconductor device after forming blocking pattern; and

FIG. 10 is a schematic top view of a semiconductor device according to the third embodiment of the present disclosure.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

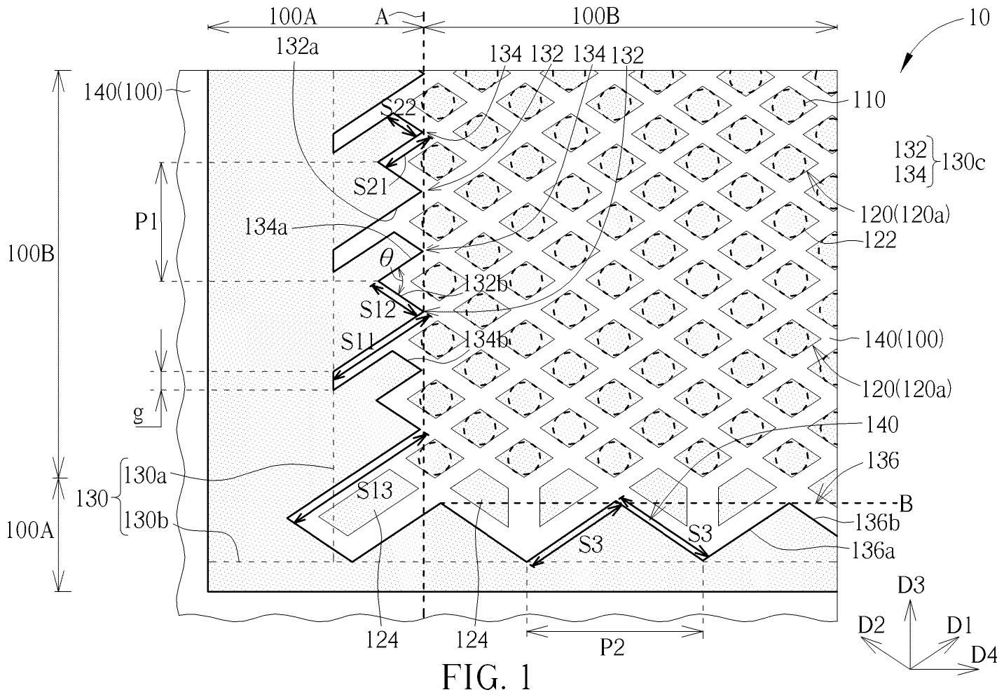

Please refer to FIG. 1, which is a schematic diagram illustrating a semiconductor device 10 according to a first embodiment of the present disclosure. The semiconductor device 10 includes a substrate 100, an extension pad array 120a and a margin structure 130. The substrate 100 for example includes a silicon substrate, a silicon-containing substrate, e.g., SiC or SiGe, a silicon-on-insulator (SOI) substrate, or a substrate formed of any other suitable material, but it is not limited thereto. The extension pad array 120a is disposed on the substrate 100, and includes a plurality of extension pads separately arranged in a first direction D1 and in a second direction D2 to present in an array arrangement, thereby serving as storage node pads (SN pads) of the semiconductor device 10. The margin structure 130 is disposed outside the extension pad array 120a, and precisely includes a first edge 130a extending along a third direction D3, and a plurality of first protrusions 132 and a plurality of second protrusions 134 alternately arranged on the first edge 130a. It is noted that, a side face 132b of one first protrusion 132 in the second direction D2 and a side face 134a of one second protrusion 134 in the first direction D1 are directly in contact with each other, with the one second protrusion 134 being disposed at one side adjacent to the one first protrusion 132, to together define an acute angle “0” between the two side faces 132b, 134a. A portion of the extension pads 120 are disposed between the two side faces 132b, 134a. With these arrangements, each first protrusion 132 and each second protrusion 134 in direct contact with each other are arranged on the margin structure 130, such that, a portion of the margin structure 130 extending in the third direction D3 substantially present in a zigzag structure, thereby entirely enhancing the device reliability and the structural stability of the margin structure 130 to the semiconductor device. Thus, the semiconductor device 10 may therefore gain better components, to achieve an optimized operation and performance.

In one embodiment, each one first protrusion 132 is connected to one second protrusion 134 adjacent to one side of the one first protrusion 132, and is spaced apart from another second protrusion adjacent to another side of the one first protrusion 132 by a distance “g”. That is, each first protrusion 132 is connected with one second protrusion 134 adjacent thereto to form a protrusion 130c, and a plurality of the protrusions 130c are separately arranged on the first edge 130a. Each protrusion 130c is separately disposed on the first edge 130a with each other by the distance “g”, and includes a V-shaped recess being together defined by the two side faces 132b, 134a, as shown in FIG. 1. People skilled in the art should fully understand that the first protrusions 132 and the second protrusion 134 may respectively include different shape, for example including a triangular shape and a quadrangular shape as shown in FIG. 1 for providing various structural supporting, but not limited thereto.

Precisely speaking, each first protrusion 132 includes a first lateral surface 132a in the first direction D1 and the side face 132b in the second direction D2, but is not limited thereto. Furthermore, the first lateral surface 132a and the side face 132b of each first protrusion 132 are respectively aligned with a side face 122 of the extension pads 120 in a row of the extension pad array 120a in the first direction D1, and a side face 122 of the extension pads 120 in a row of the extension pad array 120a in the second direction D2. The first lateral surface 132a and the side face 132b respectively include a length S11 in the first direction D1 and a length S12 in the second direction D2, and the length S11 of the first lateral surface 132a is preferably greater than the length S12 of the side face 132b, for providing various degrees of structural supporting in different directions. Each second protrusion 134 includes two side faces 134a in the first direction D1 and a second lateral surface 134b in the second direction D2, and each side face 134a and the second lateral surface 134b also respectively aligned with a side face 122 of the extension pads 120 in a row of the extension pad array 120a in the second direction D2, and a side face 122 of the extension pads 120 in a row of the extension pad array 120a in the first direction D1. The side faces 134a and the second lateral surface 134b respectively include a length S21 in the first direction D1 and a length S22 in the second direction D2, and the length S21 of the side faces 134a is preferably greater than the length S22 of the second lateral surface 134b, for also providing various degrees of structural supporting in different directions, but not limited thereto.

The margin structure 130 further includes a second edge 130b extending in a fourth direction D4 being perpendicular to the third direction D3, and a plurality of third protrusions 136 disposed on the second edge 130b. In one embodiment, the margin structure 130 may further include other portions disposed opposite to the first edge 130a and the second edge 130b, such that, the margin structure 130 is allowable to surround the extension pad array 120a as a whole, but not limited thereto. Precisely speaking, the third protrusion 136 includes a third lateral surface 136a in the first direction D1 and a fourth lateral surface 136b in the second direction D2, thereby presenting in a triangular shape, but not limited thereto. A length S3 of the third lateral surface 136a or the fourth lateral surface 136b is for example greater than the length S11 of the first lateral surface 132a, and is greater than the length S22 of the second lateral surface 134b. It is noted that at least one first protrusion 132 (for example the first protrusion 132 in connection with the second edge 130b) includes a relative greater first lateral surface 132a, with a length S13 thereof being greater than the length S3 of the third lateral surface 136a or the fourth lateral surface 136b, as shown in FIG. 1. Accordingly, the margin structure 130 may partially extend in the third direction D3 and partially extend in the fourth direction D4 to present in the zigzag structure generally having rectangular protrusions and triangular protrusions arranged in periodically order, or having rectangular protrusions arranged in sequence, so as to effectively enhance the device reliability and the structural stability of the margin structure 130. Furthermore, the first protrusions 132 are arranged on the first edge 130a by a first pitch P1 in the third direction D3, the second protrusions 134 are also arranged on the first edge 130a by the first pitch P1, and the third protrusions 136 are arranged on the second edge 130b by a second pitch P2 in the fourth direction D4, wherein the second pitch P2 is preferably greater than the first pitch P1, but not limited thereto.

Further in view of FIG. 1, tips of all first protrusions 132 and all second protrusions 134 are vertically aligned with each other in the third direction D3, and lie on the same cut line “A”. Also, tips of all third protrusions 136 are vertically aligned with each other in the fourth direction D4, and lie on the same cut line “B”. The semiconductor device 10 includes a periphery region 100A corresponding to components with a relative lower integration, and a cell region 100B corresponding to components with a relative higher integration, and the boundary between the periphery region 100A and the cell region 100B is generally defined by the cut lines “A” and “B”. For example, the aforementioned margin structure 130 is disposed within the periphery region 100A, and the extension pads 120 are disposed within the cell region 100B.

The semiconductor device 10 further includes a plurality of peripheral extension pads 124, a plurality of plugs 110 and a dielectric layer 140 disposed on the substrate 100. The peripheral extension pads 124 are respectively disposed within the periphery region 100A, between the second edge 130b and the extension pad array 120a, with each of the peripheral extension pads 124 extending in the first direction D1 or in the second direction D2, thereby providing proper protection to the extension pad array 120a. Each of the plugs 110 are separately disposed within the cell region 100B, under the corresponding one of the extension pads 120, to electrically connect the corresponding one of the extension pads 120 and an active area (not shown in the drawings) of the substrate 100 underneath, at the same time. In one embodiment, the plugs 110 for example include a conductive material, with the conductive material for example being an epitaxial material like silicon, silicon phosphorus (SiP), silicon germanium (SiGe) or germanium (Ge), or a low-resistance metal material like aluminum (Al), titanium (Ti), copper (Cu) or tungsten (W), but not limited thereto. The dielectric layer 140 is disposed between each of the extension pads 120, and between each of the peripheral extension pads 124 and the margin structure 130, for isolating each component. It is noted that a portion of the dielectric layer 140 is filled in gaps between each protrusions 130a, and is partially sandwiched between each first protrusion 132 and the second protrusion 134, to directly contact the first edge 130a. In one embodiment, the dielectric layer 140 for example includes an insulating material like silicon oxide, silicon nitride, or silicon oxynitride (SiON), but not limited thereto.

According to the semiconductor device 10 of the present embodiment, the margin structure 130 partially extends in the third direction D3 and partially extends in the fourth direction D4 to generally present in the zigzag structure, through arranging the protrusions (including the first protrusions 132, the second protrusions 134, and the third protrusions 136) on the margin structure 130. The margin structure 130 extending in the third direction D3 and extending in the fourth direction D4 may therefore present in the zigzag structures with protrusions in various shapes and various sizes, so as to improve the device reliability and the structural stability of the margin structure 130. Thus, it is sufficient to reduce the possible loading effect easily occurred at the boundary between the peripheral region 100A and the cell region 100B with different integrations, and to optimize the operation performance of the semiconductor device 10 thereby.

Those of ordinary skill in the art would easily understand that various components such as transistor components, word line components and/or bit line components may be additionally arranged either in the substrate 100, or on the substrate 100, due to practical product requirements. For example, a capacitor structure (not shown in the drawings) electrically connected to the extension pads 122 may be further arranged above the extension pad array 120a, with the capacitor structure including a plurality of capacitors (not shown in the drawings) over the extension pads 120, and with a portion of the capacitors being disposed between the first protrusions 132 and the second protrusions 134, thereby forming a dynamic random access memory (DRAM) device to achieve better device performance, but not limited thereto.

In order to make those having ordinary skills in the art easily understand the semiconductor device 10 according to the present disclosure, a method of fabricating the semiconductor device 10 according to the present disclosure will be further described as follows.

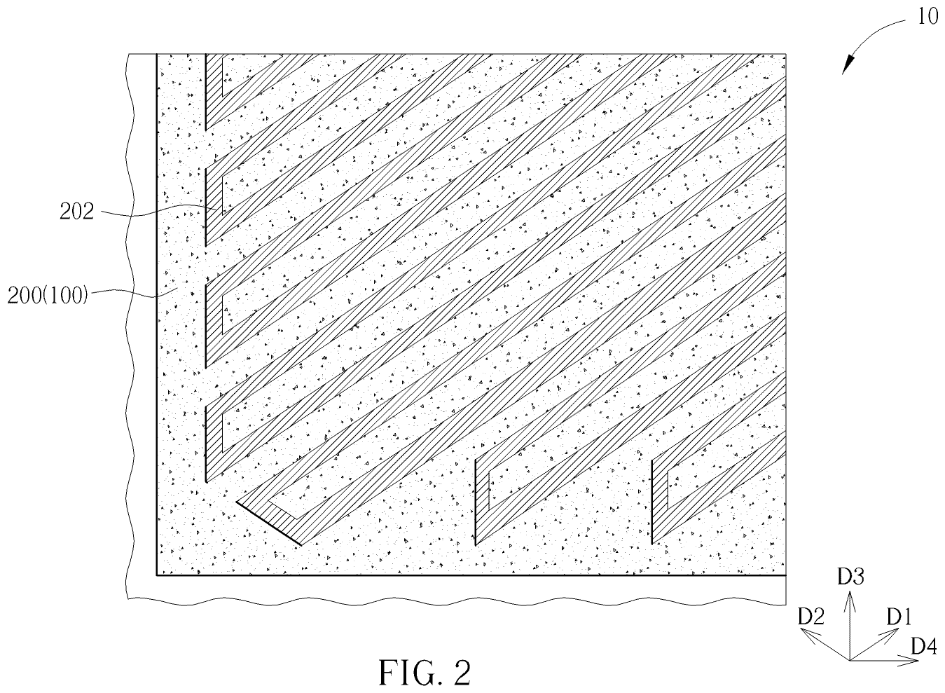

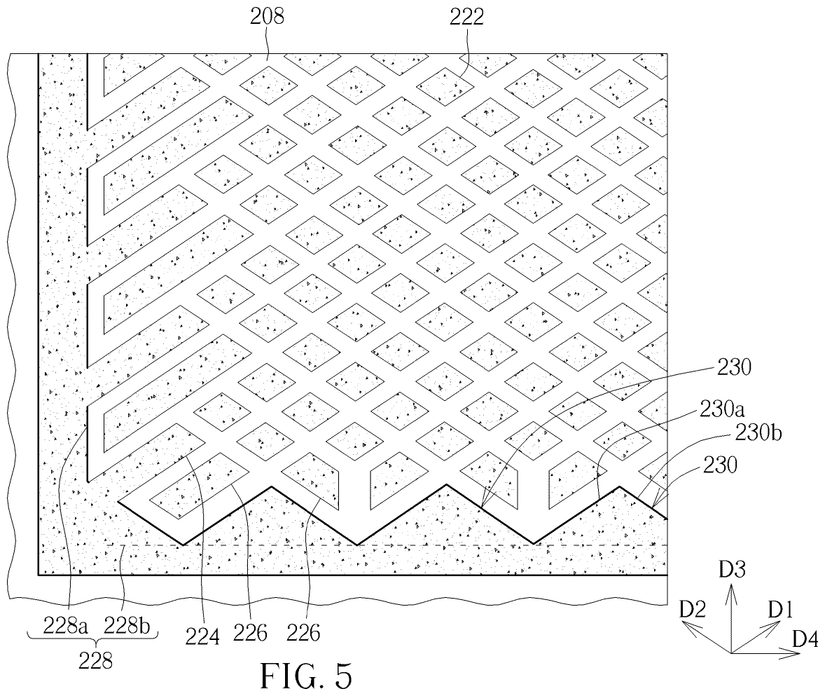

Please refer FIG. 2 to FIG. 6, which are schematic diagrams illustrating a method of fabricating a semiconductor device 10 according to the first embodiment of the present disclosure.

Firstly, the substrate 100 is provided as shown in FIG. 2, and a metal material layer (not shown in the drawings), a mask layer 208 (not shown in FIG. 2), and a hard mask layer 200 are sequentially formed on the substrate 100, entirely overlaying the substrate 100. In one embodiment, the metal material layer for example includes a low-resistance metal material like Al, Ti, Cu or W, the mask layer 208 for example includes a suitable mask material like amorphous silicon, and the hard mask layer 200 for example includes a suitable hard mask material like silicon nitride or silicon carbonitride, but not limited thereto. Then, a first self-aligned reverse patterning (SARP) process is performed to form a first mask layer 202 on the hard mask layer 200, with the first mask layer 202 having a plurality of mask patterns having a rectangular frame being separately arranged in the first direction D1.

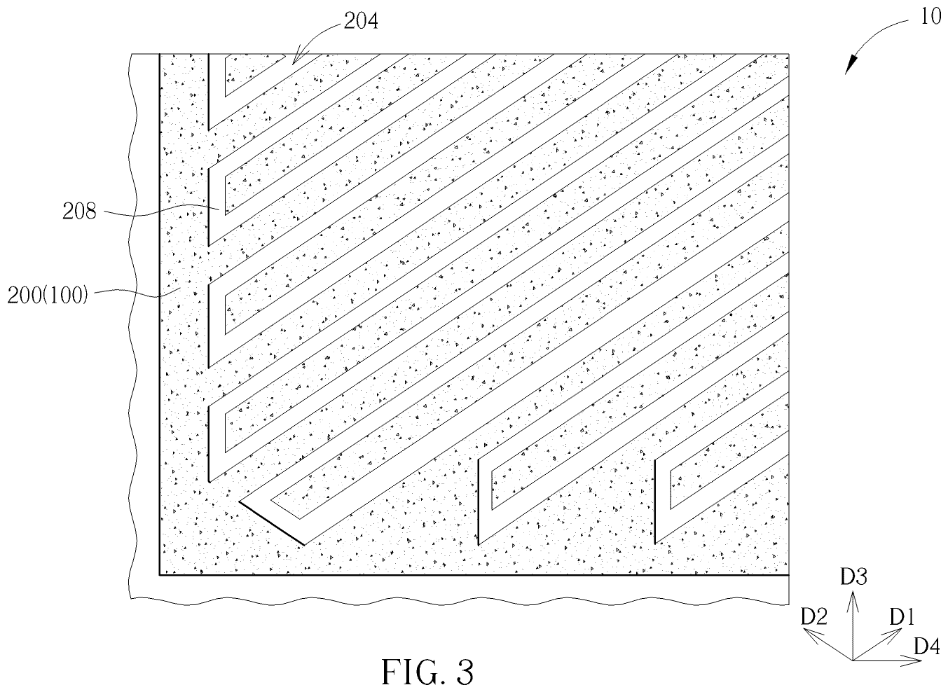

Next, as shown in FIG. 3, an etching process is performed through the first mask layer 202, to form a plurality of first openings 204 in the hard mask layer 200, with each of the first openings 204 having a rectangular frame. The first openings 204 are separately disposed in the first direction D1, exposing the mask layer 208 underneath, respectively. Then, the first mask layer 202 is completely removed.

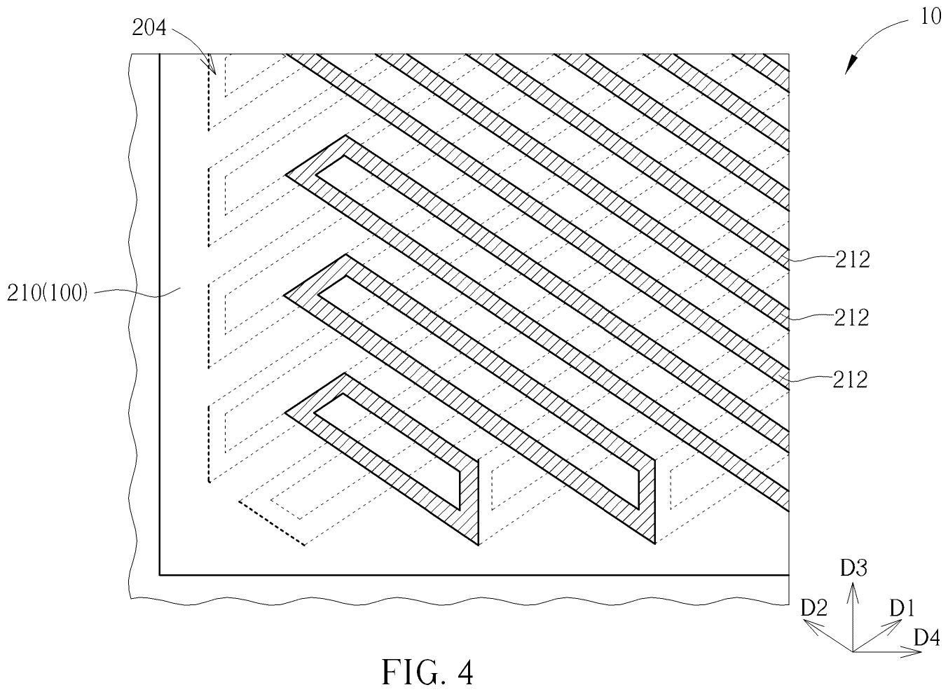

As shown in FIG. 4, a mask layer 210 is formed on the substrate 100, entirely overlaying the hard mask layer 220 and the mask layer 208, and a second mask layer 212 is formed on the mask layer 210 through performing a second SARP process. The second mask layer 212 includes a plurality of mask patterns having a rectangular frame, with each of the mask patterns separately disposed in the second direction D2, and intersecting with each of the first openings 204 underneath, respectively. In one embodiment, the mask layer 210 for example includes a suitable mask material, such as amorphous silicon, and the second mask layer 212 also includes a mask material like silicon nitride or silicon carbonitride, but not limited thereto. After that, another etching process is performed through the second mask layer 212, to form a plurality of second openings (not shown in the drawings) in a rectangular frame in the mask layer 210 and the hard mark layer 200 underneath. Then, the second mask layer 212 and the mask layer 210 are removed.

With these performances, the second openings are separately disposed in the second direction D2 to intersect with the first openings 204 underneath, thereby also exposing the hard mask layer 208 underneath. Accordingly, through performing two times SARP processes on the hard mask layer 200, a plurality of first mask patterns 222, a plurality of second mask patters 224, 226, and a third mask pattern 228 are formed, with each of the first mask patterns 222 having the same shape and size, and being separately arranged in the first direction D1 and the second direction D2 to present in an array arrangement. The third mask pattern 228 is disposed outside all of the first mask patterns 222, and which includes a first edge 228a extending along the third direction D3 and a second edge 228b extending along the fourth direction D4. The second edge 228b further includes a plurality protrusions 230 disposed thereon, with each of the protrusions 230 including an inclined faces 230a in the first direction D1 and an inclined face 230b in the second direction D2. The second mask patterns 224 are respectively extended in the first direction D1, being disposed between all of the first mask patterns 222 and the first edge 228a of the third mask pattern 228. The second mask patterns 224 are partially contact the first edge 228a of the third mask pattern 228, and partially not contact the first edge 228a of the third mask pattern 228. On the other hand, the second mask patterns 226 are respectively extended either in the first direction D1 or in the second direction D2, being substantially between all of the first mask patterns 222 and the second edge 228b of the third mask pattern 228, without directly contacting the second edge 228b of the third mask pattern 228.

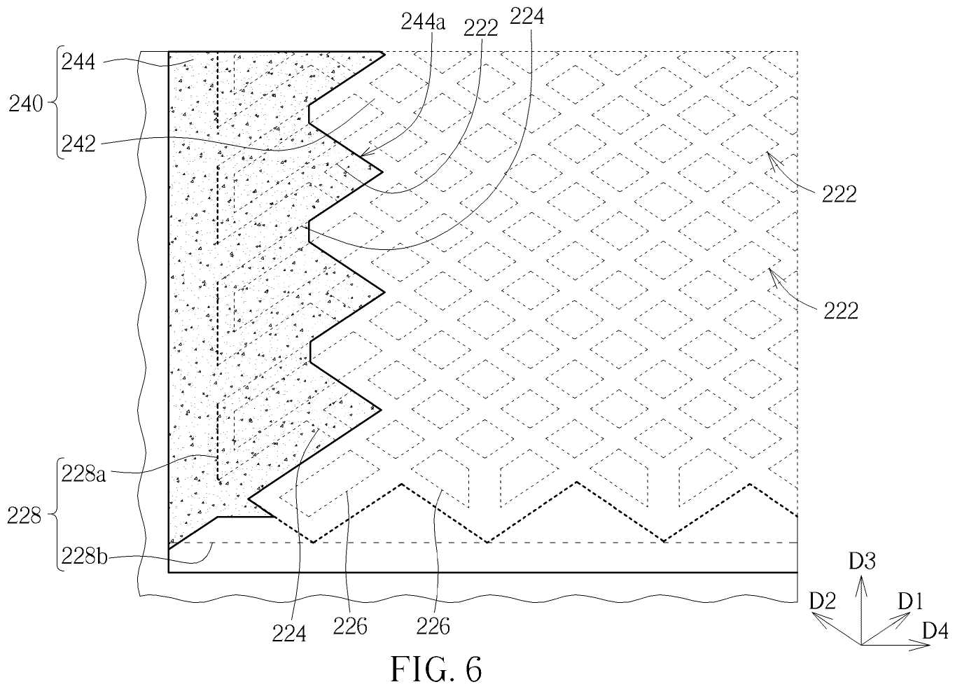

Then, as shown in FIG. 6, a mask structure 240 is formed on the substrate 100, and the mask structure 240 preferably includes a composite structure which includes but not limited to an organic bottom layer (not shown in the drawings), a silicon hard mask bottom anti-reflective coating layer 242 and a mask layer 244 stacked in sequence. The organic bottom layer and the silicon hard mask bottom anti-reflective coating layer 242 entirely overlay the hard mask layer 200 and the mask layer 208, and the mask layer 244 includes at least one blocking pattern 244a for completely shielding the first edge 228a of the third mask pattern 228, the second mask patterns 224 directly contacting the first edge 228a, and the first mask patterns 222 closed to the second mask patterns 224 directly contacting the first edge 228a in the first direction D1, and partially shielding the second mask patterns 224 without contacting the first edge 228a, with the second mask patterns 224 without contacting the first edge 228a being partially exposed from the blocking pattern 244a. It is noted that, the blocking pattern 244a includes a zigzag-shaped side, with a portion of the zigzag-shaped side in the first direction D1 overlapping a side of one second mask pattern 224 directly contacting the first edge 228a, and a side of at least one first mask patterns 222 adjacent to the one second mask pattern 224 in the first direction D1, and with a portion of the zigzag-shaped side in the second direction D2 overlapping another side of the at least one first mask pattern 222, thereby partially exposing the second mask pattern 224 without contacting the first edge 228a.

Following these, an etching process is performed through the mask structure 240, to simultaneously transfer the pattern of the blocking pattern 244a, as well as the patterns of the second mask patterns 224 and the first mask patterns 222 being revealed from the blocking pattern 244a, into the mask layer 208 underneath, and to further transfer into the metal material layer underneath, thereby forming the extension pads 120, the peripheral extension pads 124 and the margin structure 130 as shown in FIG. 1. Then, the periphery region 100A and the cell region 100B of the semiconductor device 10 are therefore defined by the margin structure 130, and the mask structure 240 is completely removed. Next, a dielectric material layer (not shown in the drawings) is formed on the substrate 100, and a planarization process is performed on the dielectric material layer, to form the dielectric layer 140 surrounding the extension pads 120, the peripheral extension pads 124 and the margin structure 130 as shown in FIG. 1.

According to the method of fabricating the semiconductor device 10 in the present embodiment, the two SARP processes are performed to commonly define the first mask patterns 222, the second mask patterns 224, 226, and the third mask pattern 228, and the blocking pattern 244a is further formed for shielding corresponding ones of the first mask patterns 222, the second mask patterns 224 and the third pattern 228. Then, the profile of the margin structure 130 is defined thereby, and also, the boundary between the peripheral region 100A and the cell region 100B are defined at the same time. It is noted that the blocking pattern 244a partially overlaps a side of one second mask pattern 224 directly contacting the first edge 228a, and two sides of one first mask pattern 222 adjacent to the one second mask pattern 224, to present in a zigzag shape. Thus, the margin structure 130 having the zigzag structure is therefore formed through the etching process based on the blocking pattern 244a, as well as the second mask patterns 224 and the first mask patterns 222 being revealed from the blocking pattern 244a, to enhance the device reliability and the structural stability of the margin structure 130. In this way, the method of fabricating the semiconductor device 10 of the present embodiment is allowable to successfully improve the structural intensity of the margin structure 130, thereby forming the semiconductor device 10 with optimized performance.

Those of ordinary skill in the art would easily understand that although the extension pad array 120a, the peripheral extension pads 124 and the margin structure 130 are formed on the substrate 100, various components such as the transistor components, the word line components and/or the bit line components may be further formed either within the substrate 100 or on the substrate 100 due to practical product requirements. In other words, the following steps include but not limited to previously perform before forming the extension pads 120. For example, a shallow trench isolation (not shown in the drawings) may be further formed in the substrate 100. Subsequently, a buried gate structure (not shown in the drawings) is formed in the substrate 100, within the cell region 100B, to server as the buried word lines of the semiconductor device 10. Then, a plurality of bit lines (not shown in the drawings) and a plurality of the plugs 110 are formed on the substrate 100, with the bit lines and the plugs 110 being alternately arranged with each other in the cell region 100B. Although the buried word line and the bit lines are not specifically depicted in the drawings of the present embodiment, those of ordinary skill in the art would easily understand that the bit lines are parallel to each other and extend in a direction perpendicular to the buried word line, i.e., the gate structure. The bit lines are electrically connected to the substrate 100 through respective bit line contacts (BLCs, not shown in the drawings) disposed thereunder, and electrically insulated from the buried word line in the substrate 100 through an insulating layer (not shown in the drawings) overlying the top surface of the substrate 100. The insulating layer for example includes a silicon oxide-nitride-oxide structure, but not limited thereto. After that, the above-mentioned processes are performed to form the extension pad array 120a, the peripheral extension pads 124, the margin structure 130 and the dielectric layer 140, such that, each of extension pads 120 may be electrically connected to each of the plugs 110. Furthermore, a capacitor structure (not shown in the drawings) electrically connected to the extension pads 120 may be further formed above the extension pad array 120a, thereby forming a DRAM device to achieve better functions and device performance.

Furthermore, those of ordinary skill in the art should easily realize the semiconductor device and the fabricating method thereof in the present disclosure are not limited to the aforementioned embodiment, and which may include other examples or varieties. The following description will detail the different embodiments of the semiconductor device and the fabricating method thereof in the present disclosure. To simplify the description, the following description will detail the dissimilarities among the different embodiments and the identical features will not be redundantly described. In order to compare e the differences between the embodiments easily, the identical components in each of the following embodiments are marked with identical symbols.

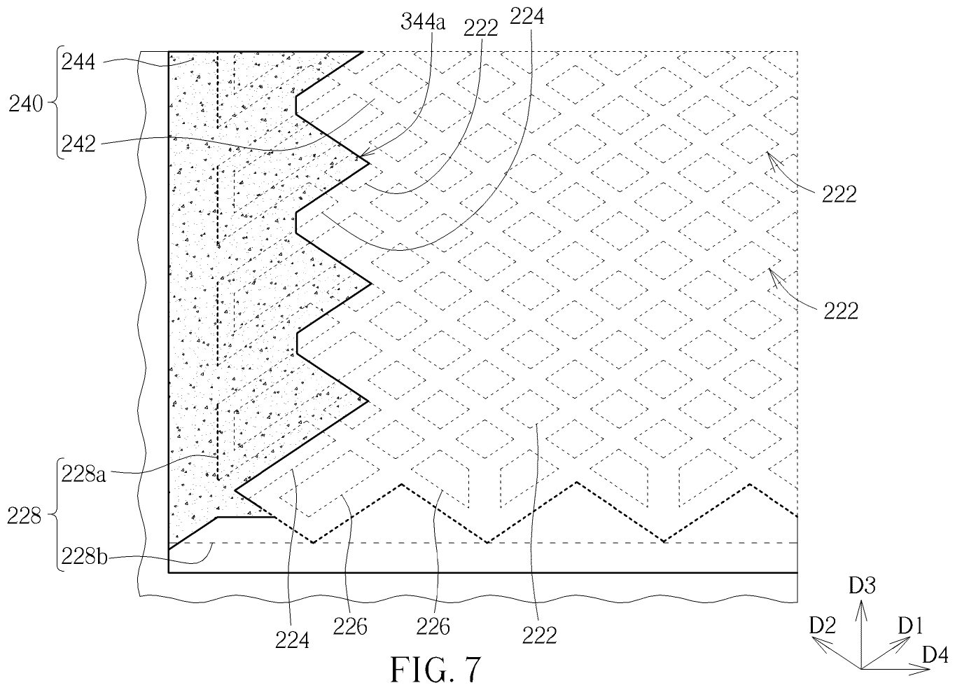

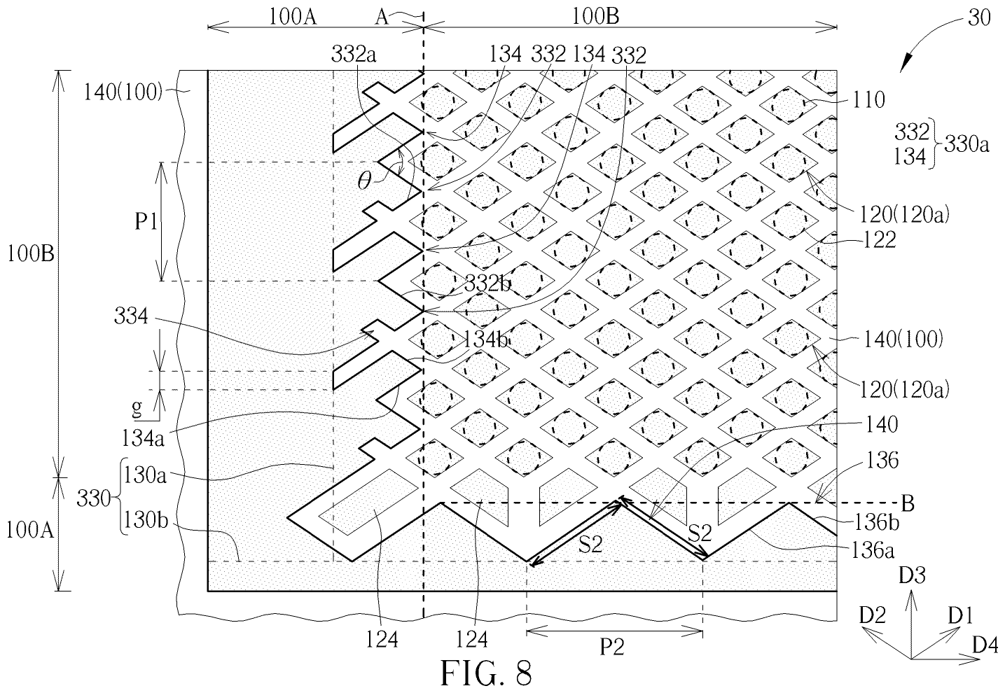

Please refer to FIG. 7 to FIG. 8, which are schematic diagrams illustrating a method of fabricating a semiconductor device 30 according to the second embodiment of the present disclosure. The method of fabricating the semiconductor device 30 in the present embodiment is substantially the same as the method of fabricating the semiconductor device 10, as shown in FIG. 2 to FIG. 5, and all the similarities will not be redundantly described hereinafter.

As shown in FIG. 7, the difference between the method of fabricating the semiconductor device 30 in the present embodiment and that of the aforementioned embodiment is mainly in that the blocking pattern 344a of the present embodiment is formed for completely shielding the first edge 228a of the third mask pattern 228, and for partially shielding all of the second mask patterns 224 and a portion of the first mask patterns 222 adjacent to the second mask patterns in the first direction D1. It is noted that the blocking pattern 344a also includes a zigzag-shaped side, with a portion of the zigzag shaped side in the first direction D1 being parallel with a side of one second mask pattern 224, without overlapping with thereto, and with a portion of the zigzag shaped side in the second direction D2 overlapping a side of one first mask pattern 222 adjacent to the second mask patterns 224, thereby partially exposing each of the second mask patterns 224 and at least one first mask pattern 222 at the same time.

After that, an etching process is performed through the mask structure 240, to transfer the pattern of the blocking pattern 344a, as well as the patterns of the second mask patterns 224 and the first mask patterns 222 revealed from the blocking pattern 344a, into the mask layer 208 underneath, and to further transfer the metal material layer underneath, to form the extension pads 120, the peripheral extension pads 124, and the margin structure 330 as shown in FIG. 8. Then, the mask structure 240 is completely removed, and the dielectric layer 140 is formed on the substrate 100, surrounding the extension pads 120, the peripheral extension pads 124, and the margin structure 330.

The structure of the semiconductor device 30 in the present embodiment is substantially the same as that of the semiconductor device 10 in the aforementioned embodiment, and all the similarities will not be redundantly described hereinafter. Precisely speaking, as shown in FIG. 8, the margin structure 330 of the present embodiment also includes the first edge 130 in the third direction D3, a plurality of first protrusions 332 and a plurality of the second protrusions 134 alternately arranged on the first edge 130a, the second edge 130b in the fourth direction D4, and a plurality of third protrusions 136 disposed on the second edge 130b. One of the first protrusions 332 is connected with one of the second protrusions 134 adjacent thereto, to together form a protrusion 330a, and a plurality of the protrusions 330a are separately arranged on the first edge 130a. Also, a portion of the dielectric layer 140 is filled in the gap (having the distance “g”) between each of the protrusions 330a. It is noted that, each of the first protrusions 332 includes a first lateral surface 332a in the first direction D1 and a side face 332b in the second direction D2, and the first lateral surface 332a further includes a recess portion 334 disposed thereon, with the recess opening of the recess portion 334 facing a corresponding second protrusion 134 adjacent thereto. Also, a portion of the dielectric layer 140 is filled in each recess portion 334, being between each first protrusion 332 and each second protrusion 134. The tips of all first protrusions 332 and all second protrusions 134 of the margin structure 330 are vertically aligned with each other in the third direction D3, to lie on the same cut line “A”, and the tips of all third protrusions 136 are vertical aligned with each other in the fourth direction D4, to line on the same cut line “B”. Accordingly, the peripheral region 100A and the cell region 100B of the present embodiment are also defined through the cut lines “A” and “B”.

Thus, according to the semiconductor device 30 of the present embodiment, the margin structure 330 will also present in the zigzag structure, through arranging the first protrusions 332, the second protrusions 134 and/or the third protrusions 136 either on the first edges 130a or on the second edges 130b, to improve the device reliability and the structural stability of the margin structure 330. Furthermore, various components such as the transistor components, the word line components and/or the bit line components may be additionally arranged either disposed in the substrate 100 or on the substrate 100, and also, the capacitor structure (not shown in the drawings) may be disposed on the extension pads 120, thereby forming a DRAM device to achieve better device performance.

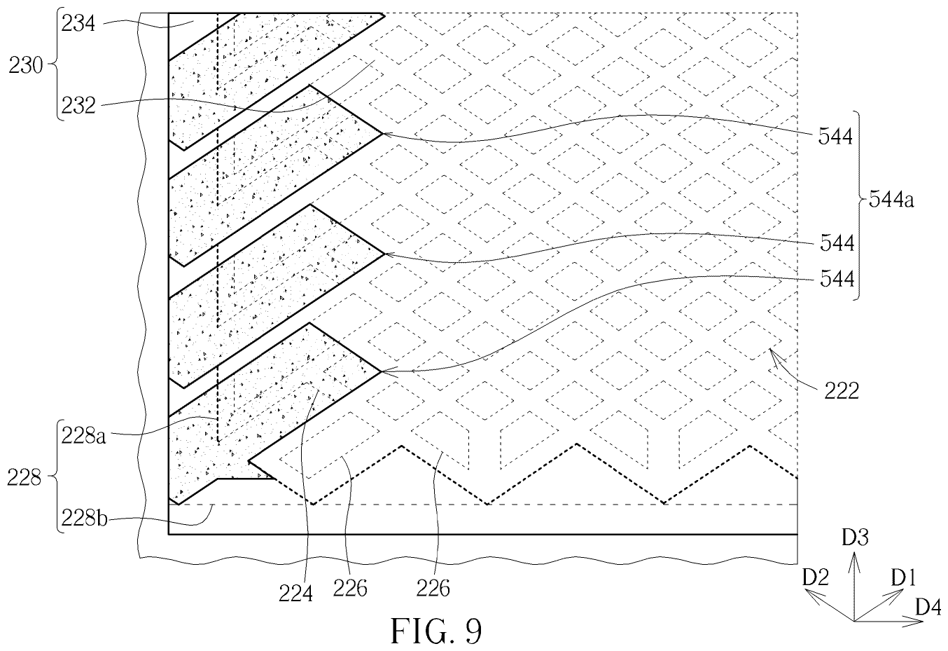

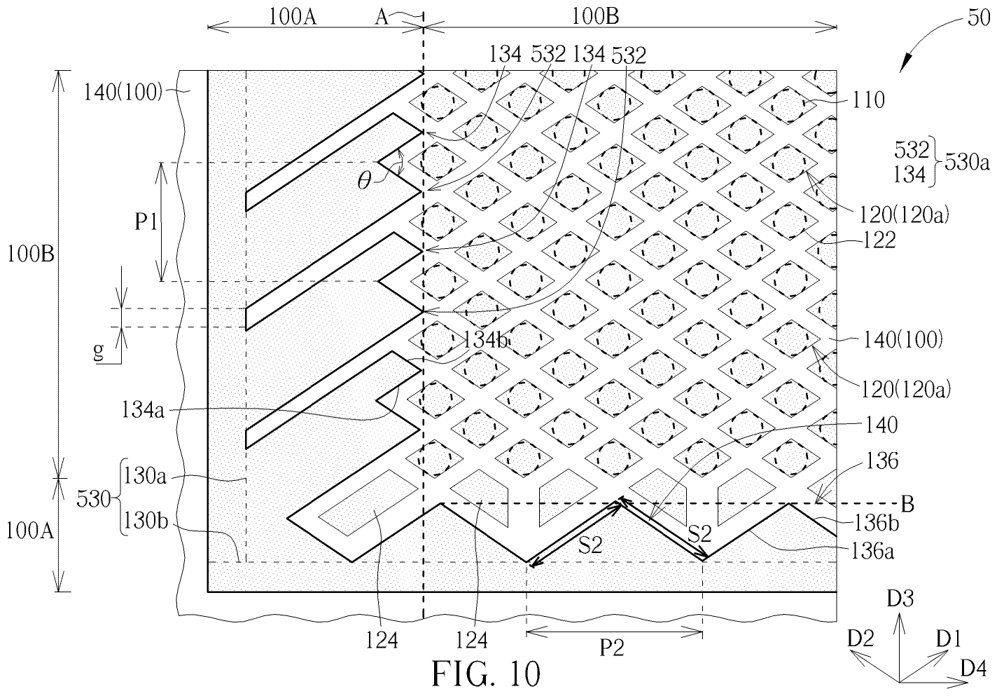

Please refer to FIG. 9 to FIG. 10, which are schematic diagrams illustrating a method of fabricating a semiconductor device 50 according to the third embodiment of the present disclosure. The method of fabricating the semiconductor device 50 in the present embodiment is substantially the same as the method of fabricating the semiconductor device 10, as shown in FIG. 2 to FIG. 5, and all the similarities will not be redundantly described hereinafter.

As shown in FIG. 9, the difference between the method of fabricating the semiconductor device 50 in the present embodiment and that of the aforementioned embodiment is mainly in that the blocking pattern 544a of the present embodiment is formed to further includes a plurality of sub-blocking patterns 544, with the sub-blocking patterns 544 being separately arranged in the third direction D3. Each of the sub-blocking patterns 544 overlays a portion of the first edge 228a, partially overlays one second mask pattern 224 without contacting the first edge 228a, and further overlays one second mask pattern 224 directly contacting the first edge 228a and one first mask pattern adjacent thereto. Accordingly, each sub-blocking pattern 544 will substantially present in a rectangular shape, with a side of the rectangular shape being parallel to and overlapping a side of one second mask pattern 224 directly contacting the first edge 228a, and a side of one second mask pattern 224 without contacting the first edge 228a, thereby partially exposing each second mask pattern 224 without contacting the first edge 228a at the same time. Following these, an etching process is performed through the mask structure 240, to transfer the pattern of the blocking pattern 544a, as well as the patterns of the second mask patterns 224 and the first mask patterns 222 being revealed from the blocking pattern 544a, into the mask layer 208 underneath, and to further transfer into the metal material layer underneath, to form the extension pads 120, the peripheral extension pads 124 and the margin structure 530 as shown in FIG. 10. Then, after removing the mask structure 240, the dielectric layer 140 is formed to surround the extension pads 120, the peripheral extension pads 124 and the margin structure 530.

Precisely speaking, as shown in FIG. 10, the margin structure 530 of the present embodiment also includes the first edge 130 in the third direction D3, a plurality of first protrusions 532 and a plurality of the second protrusions 134 alternately arranged on the first edge 130a, the second edge 130b in the fourth direction D4, and a plurality of third protrusions 136 disposed on the second edge 130b. It is noted that, one first protrusions 532 is connected to one second protrusion 134 adjacent to one side of the one second protrusion 134, and is spaced apart from another second protrusion 134 adjacent to another side of the one first protrusion 532. In other words, each first protrusion 532 is connected with one second protrusion 134 adjacent thereto to together form a protrusion 530a, and a plurality of the protrusions 530a are separated arranged on the first edge 130a.

Also, a portion of the dielectric layer 140 is filled in the gap (having the distance “g”) between each of the protrusions 530a, to directly contact a portion of the first edge 130a. Furthermore, the tips of all first protrusions 532 and all second protrusions 134 of the margin structure 530 are vertically aligned with each other in the third direction D3, to lie on the same cut line “A”, and the tips of all third protrusions 136 are vertical aligned with each other in the fourth direction D4, to line on the same cut line “B”. Accordingly, the peripheral region 100A and the cell region 100B of the present embodiment are also defined through the cut lines “A” and “B”.

Thus, according to the semiconductor device 50 of the present embodiment, the margin structure 530 will also present in the zigzag structure, through arranging the first protrusions 532, the second protrusions 134 and/or the third protrusions 136 being disposed either on the first edges 130a or on the second edges 130b, to improve the device reliability and the structural stability of the margin structure 530. Furthermore, various components such as the transistor components, the word line components and/or the bit line components may be additionally arranged either disposed in the substrate 100 or on the substrate 100, and also, the capacitor structure (not shown in the drawings) may be disposed on the extension pads 120, thereby forming the DRAM device to achieve better device performance.

Overall speaking, through arranging the margin structure having the protrusions, the semiconductor device of the present disclosure is allowable to enhance the device reliability and the structural stability of the semiconductor device, such that, the semiconductor device of the present disclosure may therefore gain an optimized operation and performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
an extension pad array comprising a plurality of extension pads disposed on the substrate, the extension pads being separately arranged in a first direction and a second direction; and
a margin structure, disposed outside the extension pad array and comprising a plurality of first protrusions and a plurality of second protrusions contacting respectively the first protrusions, wherein a side face of one of the first protrusions and a side face of one of the second protrusions adjacent to each other define an acute angle therebetween, and a portion of the extension pads is disposed between the side face of the first protrusion and the side face of the second protrusion.

2. The semiconductor device according to claim 1, wherein each of the first protrusions and each of the second protrusions respectively comprises a first lateral surface and a second lateral surface adjacent to the side face of the first protrusion and the side face of the second protrusion, and a length of the first lateral surface of each of the first protrusions is greater than a length of the second lateral surface of each of the second protrusions.

3. The semiconductor device according to claim 2, wherein the first lateral surface comprises a recess portion.

4. The semiconductor device according to claim 2, wherein a length of one of the side face of the first protrusion and the side face of the second protrusion is greater than the length of the second lateral surface.

5. The semiconductor device according to claim 1, wherein one of the first protrusions directly contacts an adjacent one of the second protrusions, and is spaced apart from another adjacent one of the second protrusions.

6. The semiconductor device according to claim 5, wherein a distance between the one of the first protrusions and the another adjacent one of the second protrusions is smaller than a length of one of the side face of the first protrusion and the side face of the second protrusion.

7. The semiconductor device according to claim 1, further comprising:
a dielectric layer, disposed on the substrate and surrounding the margin structure and the extension pads, wherein a portion of the dielectric layer is sandwiched between each of the first protrusions and each of the second protrusions.

8. A semiconductor device, comprising:
a substrate;
an extension pad array, comprising a plurality of extension pads disposed on the substrate, the extension pads being separately arranged in a first direction and in a second direction;
a margin structure, disposed outside the extension pad array and comprising a plurality of protrusions, wherein each of the protrusions comprises a V-shaped recess; and
a plurality of capacitors, respectively disposed on the V-shaped recess of each of the protrusions.

9. The semiconductor device according to claim 8, wherein each of the protrusions comprises a first protrusion and a second protrusion directly in contact with each other, and the V-shaped recess is disposed between the first protrusion and the second protrusion.

10. The semiconductor device according to claim 8, wherein the first protrusion and the second protrusion respectively comprises a first lateral surface and a second lateral surface, and a length of the first lateral surface is greater than a length of the second edge.

11. A method of fabricating a semiconductor device, comprising:
providing a substrate;
forming an extension pad array on the substrate, the extension pad array comprising a plurality of extension pads separately arranged in a first direction and a second direction; and
forming a margin structure outside the extension pad array, the margin structure comprising a plurality of first protrusions and a plurality of second protrusions respectively contacting each of the first protrusions, wherein a side face of one of the first protrusions and a side face of one of the second protrusions adjacent to each other define an acute angle therebetween, and a portion of the extension pads is disposed between the side face of the first protrusion and the side face of the second protrusion.

12. The method of fabricating the semiconductor device according to claim 11, wherein each of the first protrusions and each of the second protrusions respectively comprises a first lateral surface and a second lateral surface adjacent to the side face of the first protrusion and the side face of the second protrusion, and a length of the first lateral surface of each of the first protrusions is greater than a length of the second lateral surface of each of the second protrusions.

13. The method of fabricating the semiconductor device according to claim 12, further comprising:
forming a metal material layer on the substrate;
forming a plurality of first mask patterns, a plurality of second mask patterns, and a third mask pattern on the metal material layer; and
forming a blocking pattern on the metal material layer, overlaying the third mask pattern, a portion of the first mask patterns and the second mask patterns.

14. The method of forming the semiconductor device according to claim 13, wherein at least one of the second mask patterns is partially reveled from the blocking pattern.

15. The method of forming the semiconductor device according to claim 13, wherein at least one of the second mask patterns and at least one of the first mask patterns are both partially revealed from the blocking pattern.

16. The method of forming the semiconductor device according to claim 13, wherein the blocking pattern comprises a zigzag-shaped side.

17. The method of forming the semiconductor device according to claim 13, wherein the blocking pattern comprises a plurality of sub-blocking patterns separately disposed in the first direction.

18. The method of forming the semiconductor device according to claim 17, wherein each of the sub-blocking patterns completely overlays a side of at least one of the first mask patterns and a side of at least one of the second mask patterns.
